(19) United States
(12) Patent Application Publication
(10) Pub. No.: US 2002/0095633 A1
(43) Pub. Date: Jul. 18, 2002

(54) Electronic component, a test configuration and a method for testing connections of electronic components on a printed circuit board

(76) Inventor: Ulf Pillkahn, Muenchen (DE)

Correspondence Address: BELL, BOYD & LLOYD, LLC, P. O. BOX 1135, CHICAGO, IL, 60690-1135, US

(21) Appl. No.: 09/972,666

(22) Filed: Oct. 5, 2001

(30) Foreign Application Priority Data
Oct. 5, 2000 (DE) 10049413.7
Feb. 6, 2001 (DE) 10105251

(51) Int. Cl. G01R 31/28

(52) U.S. Cl. 714/734

(57) ABSTRACT

A method, electronic component and test configuration for testing connections of at least one electronic component on a printed circuit board, in particular solder points for connection of pins to the printed circuit board, wherein a test pulse is produced within the electronic component for at least one pin on an electronic component, a signal reflected from the pin is set such that it correlates with the test pulse, and at least one correlation value, obtained from this, is compared with a previously defined set value and is assessed.

### BACKGROUND OF THE INVENTION

The present invention relates to a method for testing connections of at least one electronic component on a printed circuit board, in particular solder points for connection of pins to the printed circuit board.

The present invention also relates to an electronic component having a test input/output and having a large number of scan registers (boundary scan cells), which make contact with the printed circuit board via pins. The present invention furthermore relates to a test configuration having a printed circuit board, having a large number of electronic components and connections between the electronic components, with the electronic components containing a test input/output and a large number of boundary scan cells, which make contact with the printed circuit board via pins.

Nowadays, printed circuit boards have a large number of electronic components (chips) which themselves have a very high density of integrated circuits (IC). The high conductor density achieved in this way on the printed circuit board is problematic for carrying out tests to find structural faults on the printed circuit board.

A large number of methods have been developed for finding such structural faults, for example by using the integrated circuit test (ICT), which tests printed circuit boards using needle board adapters, the functional printed circuit board test (FBT=Functional Board Tester), and methods which represent a combination of FBT and ICT.

The boundary scan test, which is described in detail in Parker, K. P., Boundary Scan Handbook, Boston, Mass., Kluwer Publishing 1998, was developed as an improved technique for finding faults in the structure on printed circuit boards. In comparison with the abovementioned methods, the boundary scan test has the advantage of improved fault identification and shorter programming times. However, one problem is that the test data obtained, as in the case of ICT and FBT, is transferred to an external test system which requires very complex software and a large memory for evaluation. Furthermore, the test vectors (test patterns) generated in the boundary scan test are dependent on the circuits located on the printed circuit board (they are topology-dependent), so that, in the case of complicated circuits and networks, for example in the case of networks having a number of receivers, these generated test vectors become highly complex and complicated and require memories in the Mbyte range. It is impracticable to use the boundary scan test for self-testing of the chips on the printed circuit board.

An object of the present invention, therefore, is to develop a simplified method which allows self-testing of the electronic components on the printed circuit board. Furthermore, it is intended to develop an electronic component and a test configuration for carrying out the method according to the present invention.

### SUMMARY OF THE INVENTION

Accordingly, the present invention is directed toward a method for testing connections of at least one electronic component on a printed circuit board, in particular solder points for connection of pins to the printed circuit board, in that a test pulse is produced within the electronic component for at least one pin on an electronic component, a signal reflected from the pin is set such that it correlates with the test pulse, and at least one correlation value R, obtained from this, is compared with a previously defined set value and is assessed. This allows faults to be identified and to be associated with a specific fault type; that is, for example, a fracture at a solder point on the tested pin to be identified.

In one advantageous embodiment, a large number of pins, preferably all of them, on this electronic component are tested successively, and the test result for all the pins is transmitted to a control unit.

One particular embodiment provides for the test pulse to be generated via a pseudo-random noise generator. This pseudo-random noise generator provides the test pulse or a test signal with a sufficiently fast flank rise time, so that a reflection can occur.

In order to assess a detected reflection, the correlation value R preferably can be obtained via the following steps:

a) major reduction in the delay time difference Δt of the time functions of the test pulse and of the reflected signal, by variation of Δt; and

b) multiplication of n values of the time functions of the test pulse by n values, which correspond in time, of the reflected signal, and subsequent division by the number n of values used.

A further embodiment of the method according to the present invention provides for the major reduction in the delay time differences to be carried out by assuming a predetermined value Δt for the time shift.

Furthermore, the time shift Δt can be determined independently for each pin.

In one particularly advantageous embodiment of the method according to the present invention, the time shift Δt is optimized for the identification of faults. As such, the time shift of Δt is used for when the difference between a fault-free and faulty signal is optimized.

In one preferred embodiment, a tolerance band is defined for the assessment of the correlation values R and of the set value, and is preferably statistically based on a previous measurement series.

Furthermore, the method according to the present invention can be carried out simultaneously on all the electronic components. This can be coordinated by the control unit (Board Test Controller).

The present invention further proposes that an electronic component, having a large number of boundary scan cells which make contact with a printed circuit board via pins, and having a test input/output (TAP), be developed further such that a test/control apparatus is provided in the electronic component and produces a test pulse for at least one pin, and calculates any correlation between the test pulse and a signal reflected from the at least one pin.

The test/control apparatus is preferably designed such that all the pins are tested successively, automatically.

One particular embodiment of the electronic component according to the present invention provides for the test/control apparatus to contain a pulse generator and an evaluation circuit.

In this case, the evaluation circuit may contain a memory which has at least one set value per pin. This set value preferably defines a value corresponding to a signal being reflected from this pin, without any fault having occurred. Furthermore, tolerance bands for assessment also can be stored here.

In addition, the evaluation circuit may contain an assessment part, which relates a correlation value to the set value and assesses it. This allows automatic fault association, and makes it possible to state that no fault is present.

In another advantageous embodiment of the electronic component according to the present invention, the pulse generator is in the form of a pseudo-random noise generator. The pulse generator produces virtually ideal white noise from which test pulses or test signals are obtained in a manner known per se.

A further embodiment provides for each boundary scan cell to contain an additional circuit with a multiplexer. This makes it possible to distinguish between a test mode and an operating mode.

In accordance with the basic idea of the present invention, a test configuration is also proposed. This test configuration contains a printed circuit board having a large number of electronic components and connections between the electronic components, with the electronic components containing a test input/output and a large number of boundary scan cells, which make contact with the printed circuit board via pins. The test configuration is developed further such that the electronic components are designed according to the present invention, as described above, and a control unit is provided which receives the test result for all the pins on the electronic components.

In one advantageous embodiment of the test configuration according to the present invention, the control unit is designed such that the electronic components to be tested are initialized simultaneously. Thus, since all the electronic components start the test according to the present invention at the same time, one test run for the printed circuit board or for the test configuration lasts for the time required by the electronic component having most pins.

One particularly advantageous embodiment provides for the control unit to be located on the printed circuit board.

Furthermore, the control unit can be connected via an internal and/or an external bus to at least one electronic component. Thus, if the control unit is located on the printed circuit board, it is then connected via an internal bus to at least one electronic component.

Additional features and advantages of the present invention are described in, and will be apparent from, the following Detailed Description of the Invention and the Figures.

### BRIEF DESCRIPTION OF THE FIGURES

FIG. 1 shows a known boundary scan test.

FIG. 2 shows the method according to the present invention for testing pins on a printed circuit board.

FIG. 3 shows a cross section through the connection between a chip and a printed circuit board.

FIG. 4a shows an equivalent circuit of a transmission line between two chips.

FIG. 4b shows a model of a transmission line between two chips, without any fault having occurred.

FIG. 5 shows a model of a defective transmission line between two chips resulting from a discontinuity.

FIG. 6 shows a model of a defective transmission line between two chips, resulting from a short circuit.

FIG. 7 shows a model of a defective transmission line between two chips, resulting from a bridging fault.

FIG. 8 shows a circuit for producing the pseudo-random noise.

FIG. 9 shows a diagram of the pulse sequence.

FIG. 10 shows a diagram of the test pulse sequence.

FIG. 11 shows the chip according to the present invention with a test/control unit.

FIG. 12 shows a schematic illustration of the cross-correlation in the evaluation apparatus.

FIG. 13 shows an upgraded boundary scan cell.

FIG. 14 shows the topology of the network under consideration.

FIG. 15 shows a diagram of the reflected signals for interconnects without faults, and when a fault has occurred.

FIG. 16 shows a diagram of the result of the cross-correlation for interconnects without faults, and when a fault has occurred.

### DETAILED DESCRIPTON OF THE INVENTION

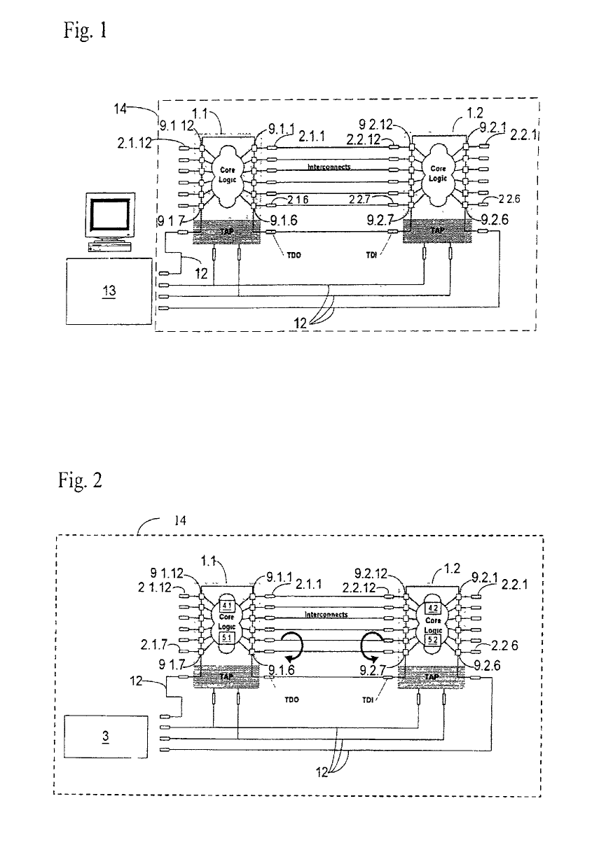

FIG. 1 shows the construction of a printed circuit board 14 with two electronic components (chips) 1.1 and 1.2 for carrying out a boundary scan test. What are referred to as scan registers (boundary scan cells) 9.X.Y are used to carry out the boundary scan test. These boundary scan cells 9.X.Y are used as monitoring points and/or as test points.

The chip 1.1 contains twelve boundary scan cells 9.1.1 to 9.1.12, which are connected to respective pins 2.1.1 to 2.1.12. Analogously, the chip 1.2 contains twelve boundary scan cells 9.2.1 to 9.2.12, connected to respective pins 2.2.1 to 2.2.12. Six interconnects run between the pins 2.1.1 to 2.1.6 and 2.2.7 to 2.2.12 and allow data to be interchanged between the chips 1.1 and 1.2. Furthermore, the chips 1.1 and 1.2 each contain a test input/output (test access port, TAP) via which they are connected via a bus system 12, referred to as a boundary scan bus, to an external test system 13. This external test system 13, thus, is not located on the printed circuit board 14.

What is referred to as an external test mode [ANSI/IEEE Standard 1149.1b “IEEE Standard Test Access Port and Boundary Scan Architecture”, IEEE Standard Board, 345 East 47th Street, New York, N.Y. 10017 1995] is used for testing the connections between the chips 1.1 and 1.2. At the start of the boundary scan test, all the boundary scan cells 9.X.Y are in what is referred to as the shift mode, in which all the cells are connected in series via the boundary scan bus.

A test pattern (test vector) is now generated in the external test system 13, and is written sequentially to the boundary scan cells 9.1.7 to 9.1.12, in the chip 1.1. By way of example, the logic values 1.0 are supplied successively to each of the six boundary scan cells 9.1.7 to 9.1.12. There is, thus, either a 0 or a 1 in each of the boundary scan cells 9.1.7 to 9.1.12.

In what is referred to as the test mode, this test pattern is now supplied to the output of these boundary scan cells 9.1.7 to 7.1.12, and is applied to the boundary scan cells 9.1.1 to 9.1.6. The test pattern is now supplied via the pins 2.1.1 to 2.1.6, the six interconnects and the pins 2.2.7 to 2.2.12 to the boundary scan cells 9.2.7 to 9.2.12 in the chip 1.2. The boundary scan cells 9.2.12 to 9.2.7 sample the values. The process now returns to the shift mode, and a chip 1.2 reads the test pattern (that is to say all 24 values) successively, via the boundary scan cells 9.2.1 to 9.2.6, and supplies this to the external test system 13.

The comparison of the test pattern (the nominal state) which has been supplied to the boundary scan cells in the chip 1.1 with the test pattern which has been received (actual state) from the boundary scan cells in the chip 1.2 is carried out in the external test system 13. If the two test patterns match, this implies that the connection between the circuits (that is to say only the relevant values of the interconnects) is serviceable.

FIG. 2 shows the embodiment according to the present invention of a printed circuit board on which the test method according to the present invention is carried out.

Analogously to FIG. 1, the printed circuit board 14 contains two chips 1.1 and 1.2, each having a large number of pins 2.X.Y and boundary scan cells 9.X.Y. The chips 1.1 and 1.2 are, in this case, however, connected via the test input/output TAP and a bus 12 to a control unit (Board Test Controller, BTC) 3, which is integrated on the printed circuit board 14.

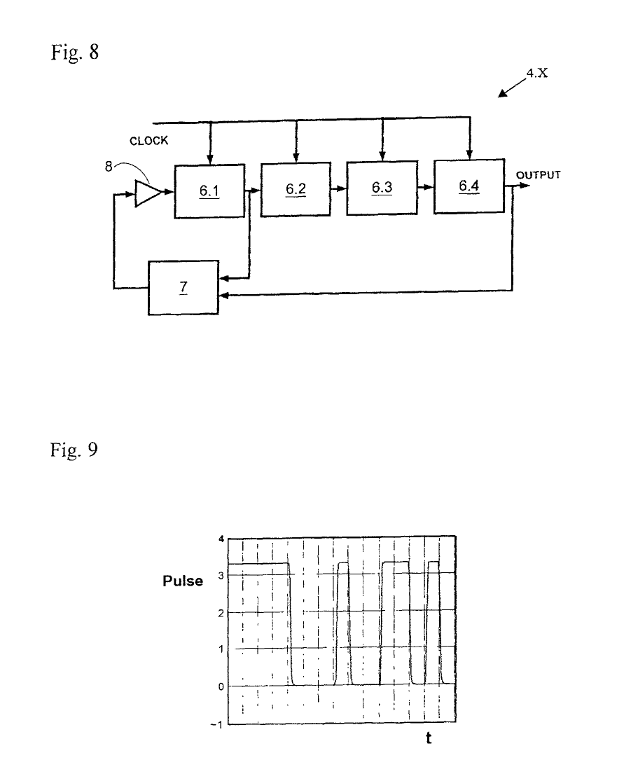

Furthermore, each chip 1.1 and 1.2 contains a pulse generator 4.X for producing a test pulse for at least one pin 2.X.Y and an evaluation apparatus 5.X, for calculating any correlation between the test pulse and a signal reflected from the at least one pin 2.X.Y. This will be described in more detail in the following text with reference to FIGS. 8, 11 and 12.

The control unit 3 preferably initializes the chips 1.1 and 1.2 simultaneously, so that they start to carry out the test at the same time. The chips 1.1 and 1.2, thus, do not influence one another during the test.

After completion of the test, the test results are supplied via the bus 12 to the control unit 3.

The circular arrows 18 are intended to indicate that the test signal need not be transmitted via the interconnects between the chips 1.X, as is the case with the boundary scan test in FIG. 1, and each chip 1.X can carry out the test according to the present invention, as a self-test on its own.

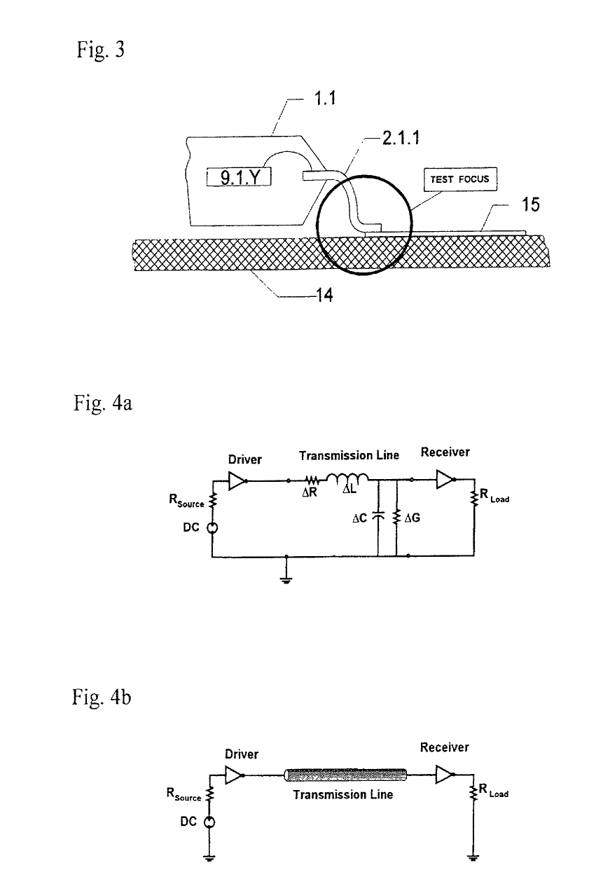

FIG. 3 shows a cross section through the connection between a chip, for example the chip 1.1, and the printed circuit board 14, with the connection representing a pin, for example the pin 2.1.1. The test method according to the present invention can verify that the solder point between the pin 2.1.1 and an interconnect (stripline) 15 on the printed circuit board 14, in this case emphasized by a circle as a “test focus”, is serviceable.

This can be achieved by considering the path from a first silicon chip to a second silicon chip as a transmission line, and by investigating a reflected signal in response to a “stimulus signal”; that is to say, a test signal. As the speed or flank gradient of the test signal rises, that is to say the rate of change of the level, the inductance of the line causes an overshoot and ringing in the case of lines with an “electrical short”, and continued wave propagation, for example a delay and reflection, in the case of “electrically long” lines.

For pin 2.1.1 to reflect signals from a pulse transmitter at its solder point, the path from the pulse transmitter to the point which is being tested, that is to say the solder point, should be “electrically long”. “Electrically long” in this case suggests that the flank gradient, that is to say the time for a pulse to rise from 0 to 1, is greater than the time that the pulse requires for the forward and return paths.

FIGS. 4 to 7 below describe different models of transmission lines, with and without a fault having occurred. Models which relate to structural faults assume that the components themselves are fault-free and that only their interconnects (=transmission line) are faulty. In this case, one interconnect connects, for example, the output of a first chip to the input of a second chip.

FIG. 4a shows the equivalent circuit of a transmission line with concentrated elements between a driver output on one chip and a receiver input on the other chip.

FIG. 4b shows the model of a fault-free transmission line, in the form of a block. This model assumes that the transmission line is loss-free, since the line impedance and the attenuation are negligible (R=0, G=0).

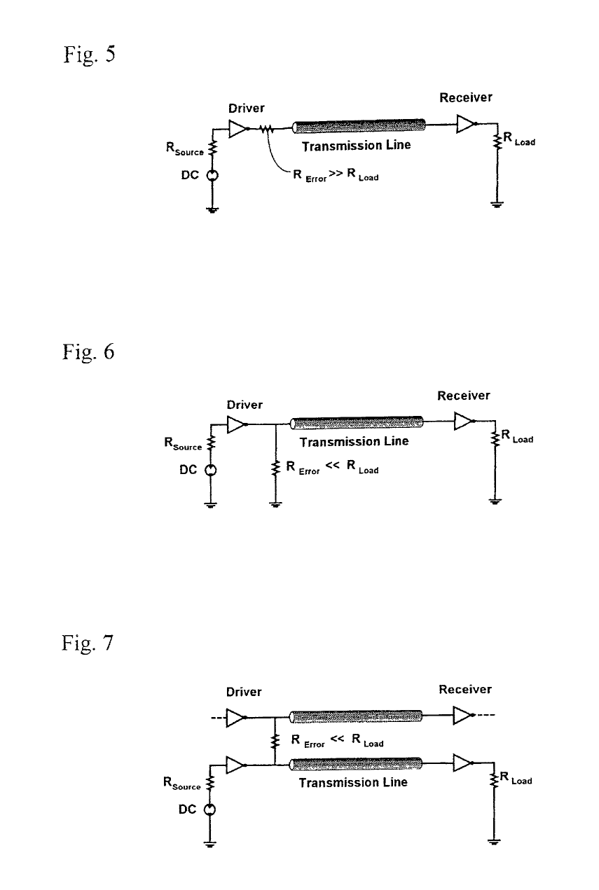

Typical faults which can occur on transmission lines such as these are, for example, a short circuit “short” or a discontinuity “open”. FIG. 5 shows the model of a defective transmission line between two chips, resulting from a discontinuity. In the model, this discontinuity is represented by a resistance R_{Error}, which is very much greater than the load resistance R_{Load}, where R_{Load} represents the input resistance of the second chip.

FIG. 6 shows the model of a defective transmission line between two chips resulting from a short circuit such as that which can occur, for example, as a result of inaccurate soldering when a solder bead connects two pins. The connection to ground or to the supply voltage (power) is in this case modeled as a resistance R_{Error} (R_{Error}≈5 Ω) which is less than the load resistance R_{Load}.

A short circuit between two signal lines is regarded as a bridge fault, with the model of this defective transmission line being shown in FIG. 7. This fault is represented by a small resistance R_{Error} (R_{Error}≦5 Ω) between the signal lines.

When an interconnect is being tested according to the present invention, the adjacent lines likewise can be monitored. If the levels on the adjacent lines change, then a bridging fault is present.

For reflections to occur on lines, the transmitted signal needs to have very fast flanks, as has been explained in FIG. 3. If, for example, an interconnect has a length of 2.5 cm, the flank rise time of a signal on the line should be shorter than 250 ps for reflections to occur. In this case, it is assumed that the interconnect has no terminating impedance, or only an inadequate terminating impedance.

Such signals with very short flank rise times may, for example, be produced by tunnel diodes or via special pulse generators. However, since these elements are very expensive, a pseudo-random noise generator also can be used instead of them. This is described in more detail in the following text with reference to FIG. 8.

FIG. 8 shows the construction of the pseudo-random noise generator 4.X. In this case, four flipflop circuits 6.X are connected in series and are clocked as shown in FIG. 8. This signal is tapped off after the first flipflop circuit 6.1 and after the fourth flipflop circuit 6.4, and is supplied to an EXOR gate 7. The output signal from the EXOR gate 7 is supplied via a buffer 8 back to the first flipflop circuit 6.1. This configuration produces a random sequence of bits.

If, for example, a 0 is supplied to the first flipflop circuit 6.1, this 0 is shifted onward through one flipflop circuit by each clock pulse. If, for example, there is now a 0 after the first flipflop circuit 6.1 and a 1 after the last flipflop circuit 6.4, the 0 and the 1 are linked by the EXOR gate 7, and a 1 is produced once again. Thus, a 1 is clocked in (latched in) as the next value upstream of the first flipflop circuit 6.1. If, however, a 1 is present after the first flipflop circuit 6.1, then the EXOR link will produce a 0. This allows a random sequence to be produced in a simple manner. This random sequence is repeated after 15 values.

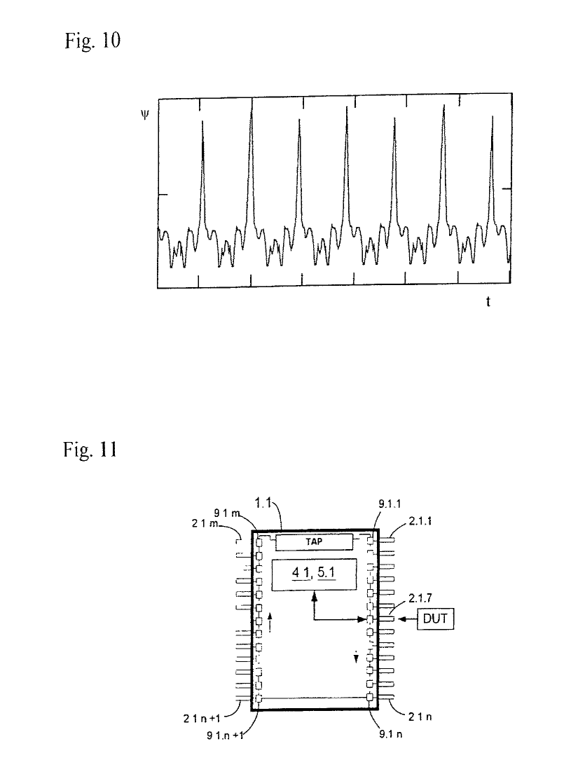

FIG. 9 shows a pulse sequence (random sequence) from the pseudo-random noise generator, showing the voltage plotted against time. The 15-bit sequence produced in this case is: 1,1,1,1,0,0,0,1,0,0,1,1,0,1,0. This is repeated continuously.

The pseudo-random noise generator can use this pulse sequence to generate approximately white noise (white noise is a totally random signal with an amplitude of 1) (pseudo-random noise). A unit pulse Φ_{XX} is produced using a known method via an autocorrelation function, as is shown in FIG. 10, plotted against time. This autocorrelation method is described, for example, by P. A. Lynn, W. Fuerst “Digital Signal Processing with Computer Application”, John Wiley 1998 and by E. C. Ifeachor “Digital Signal Processing—A Practical Approach” Addison-Wesley 1993, whose entire contents are included by way of reference.

FIG. 11 shows a chip according to the present invention, for example, the chip 1.1. This chip 1.1 has a test input/output TAP, which represents the link to a bus, a large number of boundary scan cells 9.1.Y, which each make contact with a pin 2.1.Y and a test/control unit 4.1, 5.1. This test/control unit 4.1, 5.1 controls the production of the test sequence, and its evaluation. The test/control unit 4.1, 5.1 preferably contains a pseudo-random noise generator and an evaluation circuit.

For the test, the pulse generator emits a test sequence successively to the pins 2.1.Y, and the reflected signal is passed to the evaluation circuit. The test can thus start at the pin 2.1.1, with the pins 2.1.2 to the last pin 2.1.m being tested successively. This procedure is intended to be indicated by the two arrows 17.

In the present example, the pin 2.1.7 is being tested; that is to say, this is the unit being tested at that time (device under test) DUT.

Once the test series has been completed for all the pins 2.1.Y, the information is passed on to the control unit. If, for example, the pin 2.1.4 is found to be faulty, a (preferably simple) protocol can be transmitted which may state “pin 2.1.4 is defective, other pins OK”.

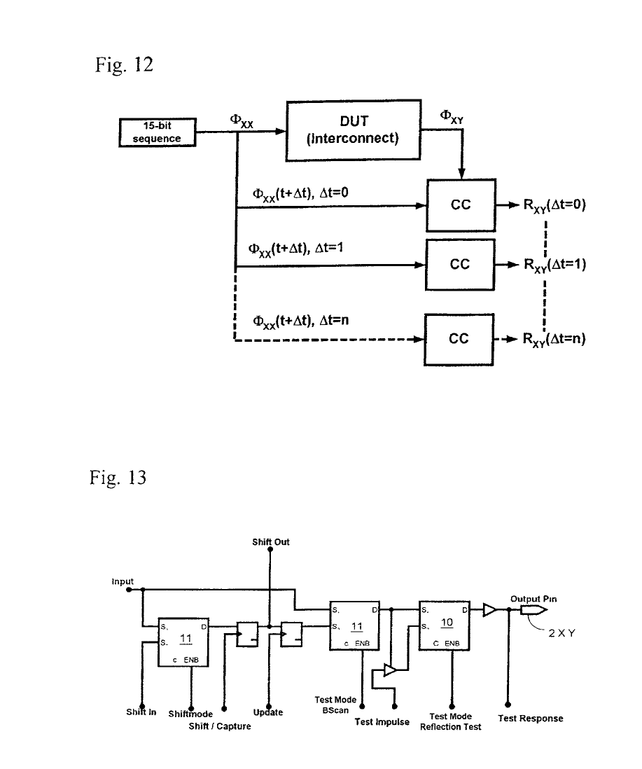

FIG. 12 shows a scheme for cross-correlation CC of an evaluation circuit, as is carried out in the electronic component. This makes it possible to assess whether or not there is any fault in a unit DUT being tested at that time.

Any correlation between the test pulse (15-bit sequence) S_{T}(t+Δt) and the signal S_{R}(t) which is reflected from the DUT and can be assessed as a fault is obtained in a number of stages:

a) Major reduction in the delay time difference Δt of the time functions of the test pulse S_{T}(t+Δt) and of the reflected signal S_{R}(t) by variation of Δt.

b) Comparison of the time functions of the test pulse S_{T}(t+Δt) and of the reflected signal S_{R}(t), by multiplication of n values of the time functions of the test pulse S_{T}(t+Δt) by n corresponding time values of the reflected signal S_{R}(t), and by subsequent division by the number n of values used, thus producing the correlation value R(Δt). This may be done as follows:

$$\frac{{\sum }_{t = 1}^{t = n} {S}_{T} ( t + Δ ) \cdot {S}_{R} ( t )}{n} = R ( Δ t )$$

The value of Δt is in this case preferably optimized for identification of faults, that is to say the value of Δt which is used is that which produces the greatest difference between the set value and the correlation value R(Δt). In this case Δt may be obtained from prior measurement or calibration.

c) Comparison of the correlation value R(Δt) with a set value which is fault-free, and assessment. It is thus possible to determine when a fault is present and the nature of this fault.

Thus, the test pulse is produced and a reflected signal is assessed within an electronic component and not in an external test system.

In order to carry out the method described above, the evaluation circuit preferably contains an assessment part, which relates the correlation value to a set value and assesses it, and a memory which has at least one set value per pin.

FIG. 13 shows an I/O circuit of a boundary scan cell 9.X.Y. This boundary scan cell 9.X.Y is upgraded in such a manner that a test pulse can be fed in without interfering with normal operation of the boundary scan cell 9.X.Y. The known boundary scan cell 9.X.Y is marked by a dashed line.

This known boundary scan cell contains two multiplexers 11. “Shift in” and “shift out” are the connections to a boundary scan bus or to a test input/output TAP in order that all the boundary scan cells 9.X.Y can be interconnected to form a chain. “Input” and “output” is the logical link which the I/O circuit uses in normal operation; that is to say, not in the test mode.

In order to upgrade the known boundary scan cell, an additional multiplexer 10 is introduced. This multiplexer 10 contains a “test pulse” input for feeding in the test sequence (for example the 15-bit sequence) from a generator, and a “test mode reflection test” input. This test sequence is reflected from the pin 2.X.Y, and is passed via a “test response” to an evaluation circuit.

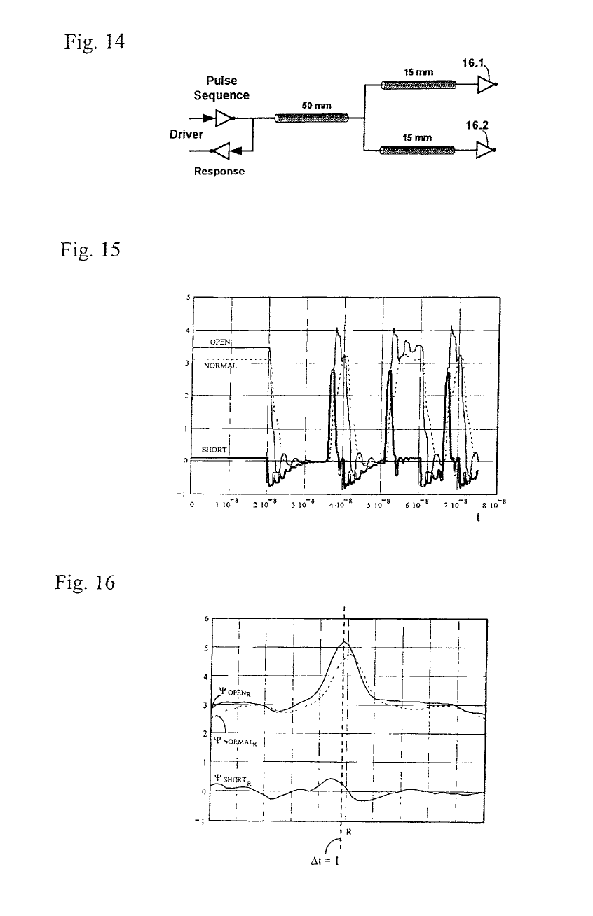

FIG. 14 shows the model of one exemplary embodiment. The method according to the present invention is carried out using a point-to-multipoint link. The driver is part of a chip and the receivers 16.1 and 16.2 are part of two different chips. The electrical length of the line is shown in FIG. 14.

FIG. 15 shows a diagram of the time functions of three reflected signals S_{R}(t), for example from three different pins, with two of these pins being faulty. The reflected signal without any faults (normal) is dotted, the reflected signal from an open line is shown as a solid line and that when a short circuit has occurred is shown as a bold solid line.

FIG. 16 shows the result of the calculated cross-correlation between the test sequence in FIG. 9 and the reflected signals from FIG. 15, with the calculated values R being plotted against the shift Δt.

Curves R_{OPEN}(Δt), R_{NORMAL}(Δt) and R_{SHORT}(Δt) with different appearances are obtained depending on the fault that is present. The difference between the resultant curves is at its greatest at Δt=1, marked by a vertical dashed line. A value R(Δt=1)=4.461 is thus obtained here for a line without any faults, a value of R(Δt=1)=5.299 with an open line, and a value of R(Δt=1)=0.277 when a short circuit is present.

The value R(Δt=1)=4.461 thus corresponds to the set value for a pin, and this is preferably stored in the evaluation unit. If, for example, a value R(Δt=1)=4.5 is obtained when carrying out the method according to the present invention, this is compared with the set value and is assessed, and it can be assumed that no fault is present.

If, on the other hand, a value is obtained which is below the set value, for example R(Δt=1)=0.3, it can be assumed that a short circuit is present, and if the value is above the set value, for example R(Δt=1)=5.2, then a discontinuity can be assumed.

A tolerance is preferably defined for the assessment between the value R and the set value.

It should be noted that the method according to the present invention is independent of the technology of the electronic components, and that analog, digital and “mixed signal” chips can be used for this method.

It is self-evident that the features of the present invention mentioned above can be used not only in the respectively stated combination but also in other combinations or on their own, without departing from the scope of the present invention.

Furthermore, the present invention provides a simplified method which allows self-testing of the electronic components on a printed circuit board by generating a test signal S_{T}(t), for example a 15-bit sequence, via a pseudo-random noise generator and supplying this to the electronic components. The signal S_{R}(t) reflected from the components is passed to an evaluation unit and is compared with the test signal.

Two tables are formed for this purpose, with the first table listing n voltage values of the test signal at specific time intervals, and the second table likewise listing n voltage values of the reflected signal at the same time intervals.

A cross-correlation is formed between the two tables, and a correlation value R is calculated using the following equation:

$$\frac{{\sum }_{t = 1}^{t = n} {S}_{T} ( t + Δ t ) \cdot {S}_{R} ( t )}{n} = \frac{{\sum }_{t = 0}^{t = n} {Φ}_{X Y} ( Δ t )}{n} = R ( Δ t )$$

In this case, Δt is the time shift between the tables and Δt=0 when the values of the test signal and of the reflected signal are used at the same time t; that is, when there is no time shift between the values in the two tables.

If there is a time shift whose value is Δt between the values in the tables, then the reflected signals at the time t are cross-correlated with the test signals at the time t+Δt and a correlation value R is obtained with the shift Δt.

The value of Δt which is used is, in this case, preferably that which allows optimum fault identification, that is to say that which allows a clear distinction between a set value and the correlation value R(Δt) when a fault is present. This optimal value of Δt can, in this case, be obtained from an initial experimental trial.

Furthermore, an electronic component and a test configuration are developed for carrying out the method according to the present invention.

Although the present invention has been described with reference to specific embodiments, those of skill in the art will recognize that changes may be made thereto without departing from the spirit and scope of the invention as set forth in the hereafter appended claims.

1. A method for testing connections of at least one electronic component on a printed circuit board, the method comprising the steps of:
producing a test pulse within the electronic component for at least one pin on the electronic component;
setting a signal reflected from the pin such that it correlates with the test pulse; and
comparing at least one correlation value, obtained from the reflected signal, with a previously defined set value and thereafter assessing the correlation value.

2. A method for testing connections of at least one electronic component on a printed circuit board as claimed in claim 1, the method further comprising the steps of:
testing successively a plurality of pins on the electronic component; and
transmitting a test result for the plurality of pins to a control unit.

3. A method for testing connections of at least one electronic component on a printed circuit board as claimed in claim 1, the method further comprising the step of:
generating the test pulse via a pseudo-random noise generator.

4. A method for testing connections of at least one electronic component on a printed circuit board as claimed in claim 1, the method further comprising the step of:
obtaining the correlation value by a major reduction in delay time difference of time functions of the test pulse and of the reflected signal, by variation of the delay time difference, and multiplication of n values of the time functions of the test pulse by n values, which correspond in time, of the reflected signal, and subsequent division by the number n of values used.

5. A method for testing connections of at least one electronic component on a printed circuit board as claimed in claim 4, wherein the major reduction in the delay time differences is carried out by assuming a predetermined value for the delay time difference.

6. A method for testing connections of at least one electronic component on a printed circuit board as claimed in claim 4, wherein the delay time difference is determined independently for each pin.

7. A method for testing connections of at least one electronic component on a printed circuit board as claimed in claim 4, wherein the delay time difference is optimized for identification of faults.

8. A method for testing connections of at least one electronic component on a printed circuit board as claimed in claim 1, the method further comprising the step of:
defining a tolerance band for the assessment of the correlation value and of the set value, wherein it is statistically based on a previous measurement series.

9. A method for testing connections of at least one electronic component on a printed circuit board as claimed in claim 1, wherein the method is simultaneously performed on a plurality of electronic components.

10. A method for testing connections of at least one electronic component on a printed circuit board as claimed in claim 1, the method further comprising the step of:
monitoring adjacent pins, during measurement of a pin, so as to identify identify crosstalk.

11. An electronic component, comprising:
a plurality of boundary scan cells which make contact with a printed circuit board via pins;
a test input/output; and
a test/control apparatus having a part for producing a test pulse for at least one pin and having a part for calculating any correlation between the test pulse and a signal reflected from the at least one pin.

12. An electronic component as claimed in claim 11, wherein the test/control apparatus is designed such that all of the pins are tested successively automatically.

13. An electronic component as claimed in claim 11, wherein the test/control apparatus contains a pulse generator and an evaluation circuit.

14. An electronic component as claimed in claim 13, wherein the evaluation circuit contains a memory which has at least one set value per pin.

15. An electronic component as claimed in claim 13, wherein the evaluation circuit contains an assessment part which relates a correlation value to a set value and assesses the correlation value.

16. An electronic component as claimed in claim 13, wherein the pulse generator is a pseudo-random noise generator.

17. An electronic component as claimed in claim 13, wherein each boundary scan cell contains an additional circuit with a multiplexer.

18. A test configuration having a printed circuit board, comprising:
a plurality of electronic components with connections therebetween, the electronic components containing a test input/output and a plurality of boundary scan cells which make contact with the printed circuit board via pins, each electronic component including a test/control apparatus having a part for producing a test pulse for at least one pin and having a part for calculating any correlation between the test pulse and a signal reflected from at least one pin; and
a control unit which receives a test result for all the pins on the electronic components.

19. A test configuration having a printed circuit board as claimed in claim 18, wherein the control unit is designed such that the electronic components to be tested are initialized simultaneously.

20. A test configuration having a printed circuitboard as claimed in claim 18, wherein the control unit is located on the printed circuit board.

21. A test configuration having a printed circuit board as claimed in claim 18, wherein the control unit is connected via at least one of an internal and an external bus to at least one of the electronic components.
